(19) United States
(12) Patent Application Publication
(10) Pub. No.: US 2007/0113133 A1
(43) Pub. Date: May 17, 2007

(54) SYSTEM AND METHOD FOR TESTING A SERIAL PORT

(75) Inventors: Qian-Sheng Liu, Shenzhen (CN); Ke-You Hu, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/309,790

(22) Filed: Sep. 27, 2006

(30) Foreign Application Priority Data
Oct. 21, 2005 (CN) 200510100589.3

(51) Int. Cl. G06F 11/00; G01R 31/28

(52) U.S. Cl. 714/736

(57) ABSTRACT

The present invention provides a method for testing a serial port. The method includes the steps of: creating a transmission loop by connecting pins of the serial port; defining testing parameters, and reference values corresponding to the testing parameters; importing a test file that comprises test data; transmitting the test data into the transmission loop according to the reference values of the testing parameters; acquiring actual values of the testing parameters during transmitting; receiving data from the transmission loop; comparing the transmitted data with the received data and comparing the actual values with the reference values of the testing parameters; and analyzing whether the serial port is in a good working condition according to comparison results. A related system is also disclosed.

### FIELD OF THE INVENTION

The present invention relates to a system and method for testing a serial port.

### DESCRIPTION OF RELATED ART

A serial port is a port or interface that can be used for serial communication in which only data is transmitted in or out one bit at a time. Most serial ports on personal computers conform to the RS-232C or RS-422 standards. A serial port can be used for almost any type of device, including modems, scanners, mice, handwriting boards, and printers. A serial port can typically be either a male connector or a female cable connector. The serial port can consist of either 25 pins or 9 pins. Whether the serial port is a 9-pin or 25-pin they both can accomplish the same set of tasks. However, nowadays, 9-pin serial ports are more common than 25-pin serial ports.

The serial ports need to be tested before being put into market. The purpose of the serial port test is to test functions of the serial ports installed in a computer. Typically, the serial port test is done by utilizing a test device that can support a serial port communication, such as a serial mouse or a serial modem.

However, the above mentioned test practice has many disadvantages. For example, each computer requires one serial device for each test, when a mass of serial ports need to be tested, the peripheral devices are prone to be destroyed easily, resulting in testing costs increase and testing efficiency affected significantly. Furthermore, such test does not provide any intuitive interface for a tester. The tester cannot view actual values of corresponding testing parameters at any moment in the testing process, such as changes of baud rates during testing.

What is needed, therefore, is a system and method that can test serial ports of a computer without any peripheral devices, and can provide an intuitive user interface for displaying actual values of corresponding testing parameters in real time.

### SUMMARY OF THE INVENTION

A system for testing a serial port is provided. The system includes a creating module, a configuration module, a transmitting module, an analyzing module, and a receiving module. The creating module is configured for creating a transmission loop by connecting pins of the serial port. The configuration module is configured for defining testing parameters and reference values corresponding to the testing parameters. The transmitting module is configured for importing a test file that comprises test data, for transmitting the test data into the transmission loop according to the reference values of the testing parameters. The receiving module is configured for acquiring actual values of the testing parameters during transmitting, for receiving data from the transmission loop. The analyzing module is configured for comparing the transmitted data with the received data, for comparing the actual values with the reference values of the testing parameters, and for analyzing whether the serial port is in a good working condition according to comparison results.

Furthermore, a method for testing a serial port is provided. The method includes the steps of: creating a transmission loop by connecting pins of the serial port; defining testing parameters, and reference values corresponding to the testing parameters; importing a test file that comprises test data; transmitting the test data into the transmission loop according to the reference values of the testing parameters; acquiring actual values of the testing parameters during transmitting; receiving data from the transmission loop; comparing the transmitted data with the received data and comparing the actual values with the reference values of the testing parameters; and analyzing whether the serial port is in a good working condition according to comparison results.

Moreover, another system for testing a serial port is provided. The system includes a creating module, a configuration module, a transmitting module, an analyzing module, and a receiving module. The creating module is configured for creating a transmission loop by connecting pins of the serial port. The configuration module is configured for defining testing parameters and reference values corresponding to the testing parameters, and for defining a user interface comprising a plurality of dialogue boxes for displaying the testing parameters and the corresponding reference values. The transmitting module is configured for importing a test file that comprises test data, for transmitting the test data into the transmission loop according to the reference values of the testing parameters. The receiving module is configured for acquiring actual values of the testing parameters during transmitting, for receiving data from the transmission loop. The analyzing module is configured for comparing the actual values with the reference values of the testing parameters, and for analyzing whether the serial port is in a good working condition according to a comparison result.

Other advantages and novel features of the present invention will become more apparent from the following detailed description of preferred embodiments when taken in conjunction with the accompanying drawings.

### BRIEF DESCRIPTION OF THE DRAWINGS

FIG. 1 is a schematic diagram of a hardware configuration of a system for testing a serial port in accordance with one preferred embodiment;

FIG. 2 is a schematic diagram of connections between pins of a serial port;

FIG. 3 is a schematic diagram of main software function modules of the system of FIG. 1;

FIG. 4 is a schematic diagram of a user interface of the system of FIG. 1; and

FIG. 5 is a flowchart of a method for testing a serial port in accordance with one embodiment.

### DETAILED DESCRIPTION OF THE INVENTION

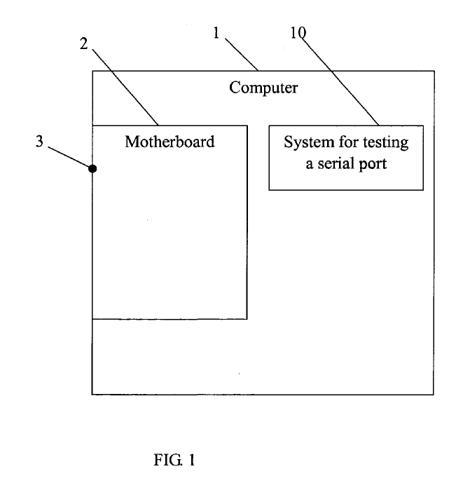

FIG. 1 is a schematic diagram of a hardware configuration of a system for testing a serial port in accordance with one preferred embodiment. The system for testing a serial port j(hereinafter, “the system”) 10 is implemented in a computer 1. The computer 1 may include a motherboard 2 and a serial port 3 configured with the motherboard 2.

A 9-pin serial port 3 conforming to the recommended standard-232C (RS-232C) is selected for an example in the preferred embodiment. The RS-232C is a standard that describes a physical interface and a communications protocol. The RS-232C is commonly used in the computers to communicate and exchange data with modems and other serial devices, and it specifies signal levels, data formats, maximum transmission distance, etc.

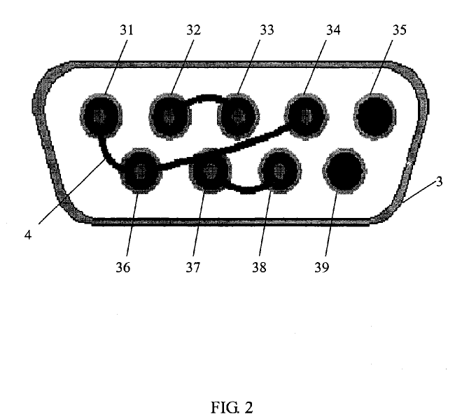

FIG. 2 is a schematic diagram of connections between pins of the serial port 3. The serial port 3 includes 9 pins: a data-carrier-detect (DCD) pin 31, a receive-data (RxD) pin 32, a transmit-data (TxD) pin 33, a data-terminal-ready (DTR) pin 34, a signal-ground (SG) pin 35, a data-send-ready (DSR) pin 36, a request-to-send (RTS) pin 37, a clear-to-send (CTS) pin 38, and a ring indicator (RI) pin 39.

As shown in FIG. 2, certain pins of the serial port 3 are connected by a plurality of loop back plugs 4 so as to form a transmission loop. The connections includes a connection between the RxD pin 32 and the TxD pin 33, a connection between the RTS pin 37 and the CTS pin 38, and a connection between the DCD pin 31, the DSR pin 36, and the DTR pin 34. Such connections would allow data to be transmitted in the transmission loop. When a serial port test starts, test data is sent out from the TxD pin 33 thru the transmission loop, and received by the RxD pin 32.

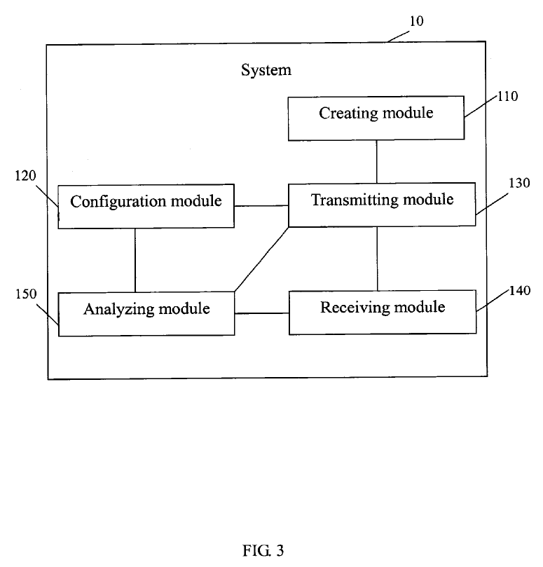

FIG. 3 is a schematic diagram of main software function modules of the system of FIG. 1. The system 10 is configured for testing the serial port 3, and for analyzing whether the serial port 3 is in good working condition. The system 10 includes a creating module 110, a configuration module 120, a transmitting module 130, a receiving module 140, and an analyzing module 150. The creating module 110 is configured for creating the transmission loop by connecting the pins of the serial port 3 as shown in FIG. 2.

The configuration module 120 is configured for defining testing parameters and reference parameters according to testing requirements, and for defining reference values corresponding to the testing parameters. The reference parameters are configured for recording related parameters corresponding to the testing process, such as a start time and an end time of the testing process. A tester may modify the reference values through the configuration module 120. The testing parameters include a baud rate, a parity bit, a size of a test file, a data bit, a stop bit, etc. For example, the baud rate indicating a speed of data transmission is set to be 9600.

The configuration module 120 is further configured for defining a user interface, various dialogue boxes in the user interface, and functions corresponding to the dialogue boxes. For example, the configuration module 120 defines functions to the dialogue boxes for displaying different information (described in detail in relation to FIG. 3).

For example, since the pins of the serial port 3 have different signal statuses, the configuration module 120 defines a signal status dialogue box to display different colors corresponding to different signal statuses of the pins of the serial port 3. The signal statuses of the pins of the serial port 3 include a high level status, a low level status, and a twinkling status. After the creating module 110 creates the transmission loop, before data is transmitted, the signal status of the DCD pin 31, the DTR pin 34, and the DSR pin 36 are in the high level status, and the signal statuses of the other pins are in the low level status. Once data transmission begins, the signal statuses of the RTS pin 37 and the CTS pin 38 change to the high level statuses, and the signal statuses of the RxD pin 32 and the TXD pin 33 change to the twinkling statuses. After data transmission has finished, the signal statuses of the RTS pin 37 and the CTS pin 38 change to the low level statuses. The configuration module 120 defines red color representing the high level statuses, and defines white color representing the low level statuses. Thus, the signal status dialogue box displays different colors or twinkles according to the signal statuses of the pins of the serial port 3.

The transmitting module 130 is configured for importing a test file that includes test data, and for transmitting the test data into the transmission loop according to the reference values of the testing parameters. The test file is stored in the computer 1, and may use an American national standards institute (ANSI) character set. For example, the transmitting module 130 transmits the test data with a baud rate of 9600. The data transmitted, a percentage of the transmission successfully transmitted, and a baud rate curve that shows changes of the baud rate during transmitting are defined to be displayed on the user interface (as shown in FIG. 3) in real time.

The receiving module 140 is configured for acquiring actual values of the testing parameters and the reference parameters during transmitting, and for receiving data from the transmission loop and storing the received data in the computer 1. If the serial port 3 is in a good working condition, the data transmitted by the transmitting module 130 are first transmitted out the TxD pin 33 of the serial port 3, then through the loop back plugs 4, and finally received by the RxD pin 32 of the serial port 3. Otherwise, the data received by the RxD pin 32 may be not identical with the data transmitted by the transmitting module 130, or even worst, the serial port 3 may not receive any data at all.

The analyzing module 150 is configured for analyzing whether the signal statuses of pins of the serial port 3 are correct according to the colors displayed in the predefined signal status dialogue box. The analyzing module 150 is further configured for comparing the transmitted data and the received data, for comparing the actual values and the reference values of the testing parameters, and for analyzing whether the serial port 3 is in a good working condition according to comparison results.

If the signal statuses of the pins of the serial port 3 are incorrect, if the transmitted data and the received data are not identical, or if the actual values and the reference values are not identical, the analyzing module 150 analyzes that the serial port 3 has errors and prompts the tester about the errors. Otherwise, if the signal statuses of the pins of the serial port 3 are correct, the transmitted data and the received data are identical, and the actual values and the reference values are identical, the analyzing module 150 analyzes the serial port 3 is in a good working condition.

The analyzing module 150 compares the above information according to one or more verification means. The verification means includes a parity check, a cyclic redundancy check (CRC), or a checksum verification. For example, the analyzing module 150 utilizes the verification means by following steps of: executing the checksum verification before the transmitting module 130 transmits the test data; acquiring a first checksum result; adding CRC codes in the data to be transmitted; executing the CRC after the data transmitted is received; deleting the CRC codes from the data received; executing the checksum verification for a second time; acquiring a second checksum result; comparing the first checksum result and the second checksum result; and analyzing whether the received data are identical with the transmitted data.

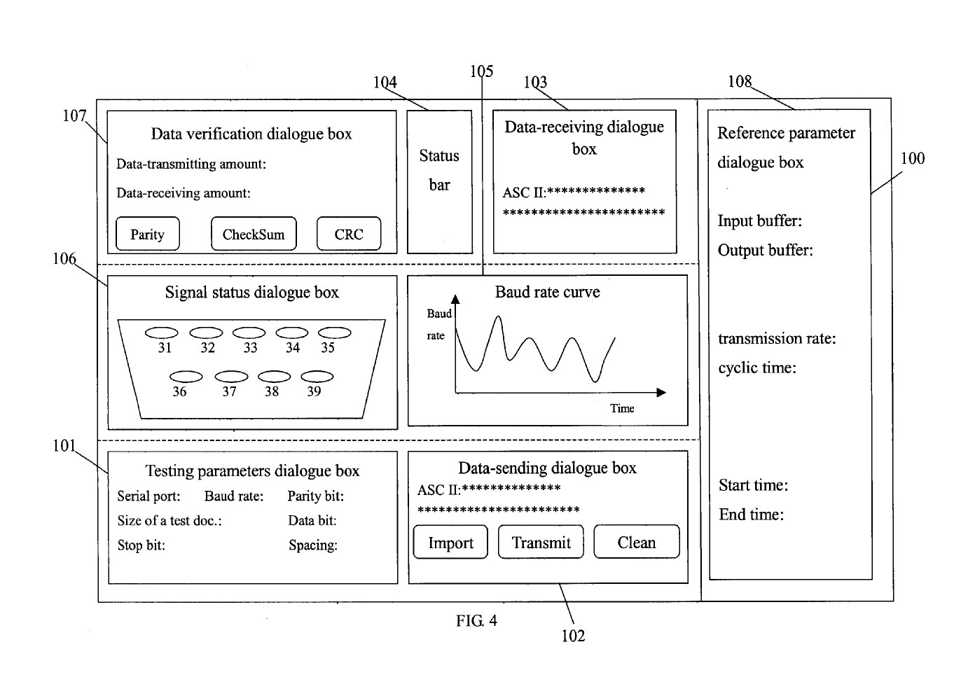

FIG. 4 is a schematic diagram of a user interface of the system of the FIG. 1. The configuration module 120 defines the user interface 100, which includes 8 dialogue boxes: a testing parameters dialogue box 101, a data-transmitting dialogue box 102, a data-receiving dialogue box 103, a status bar 104, a baud rate curve 105, a signal status dialogue box 106, a data verification dialogue box 107 and a reference parameter dialogue box 108. All the dialogue boxes are defined by the configuration module 120 to display different information.

The testing parameters dialogue box 101 displays the testing parameters defined by the configuration module 120, such as the serial port 3 to be tested, the baud rate, etc. The data-transmitting dialogue box 102 displays the data being transmitting and provides three clickable options: a first clickable option for importing a test file, a second clickable option to start transmitting the test data in the test file, and a third clickable option for clearing the displayed data. As shown in FIG. 4, some ASCII characters are displayed in the data-transmitting dialogue box 102.

The data-receiving dialogue box 103 displays the received data. The status bar 104 displays the percentage of the transmission successfully transmitted. The baud rate curve 105 displays the changes of the baud rate during transmitting. The signal status dialogue box 106 displays different colors or twinkles indicating different signal statuses of the pins of the serial port 3.

The data verification dialogue box 107 provides statistics data assisting the tester to analyze whether the transmission is normal. The statistics data include a data-transmitting amount and a data-receiving amount. The statistics data are updated in real time. The data verification dialogue box 107 also provides three clickable options for verifying the received data: a parity check option, a checksum verification option, and a cyclic redundancy check option. The reference parameter dialogue box 108 displays other reference parameters related with the testing process, such as an input buffer, an output buffer, etc.

All the functions of the dialogue boxes, the testing parameters, and the reference parameters shown in FIG. 4 are just for examples, and can be modified, added or deleted by the tester by utilizing the configuration module 120 according to testing requirements.

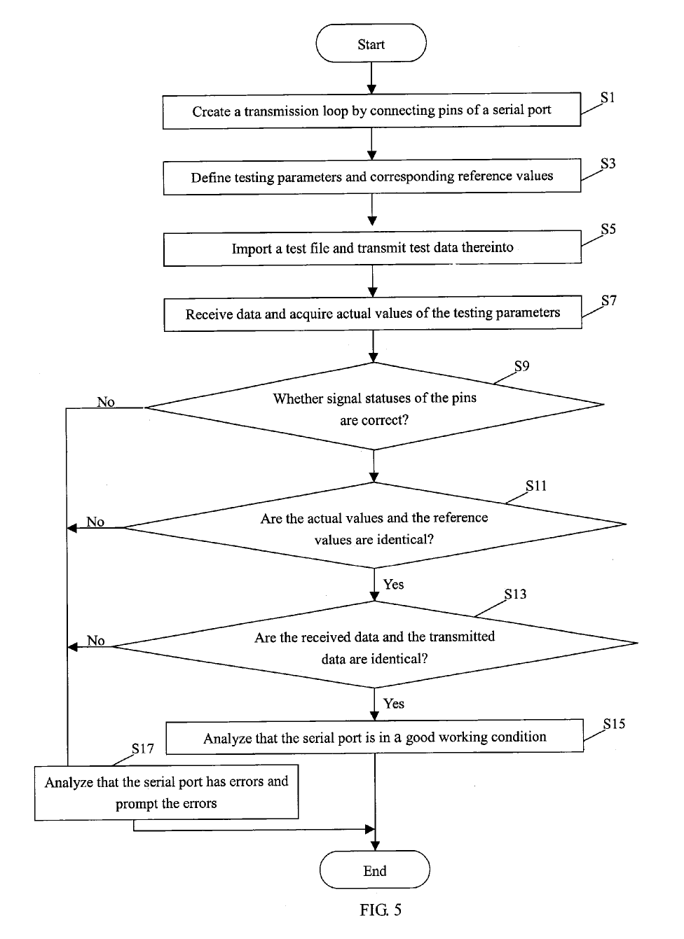

FIG. 5 is a flowchart of a method for testing a serial port in accordance with one embodiment. In step S1, the creating module 110 creates the transmission loop by connecting the pins of the serial port 3 with the loop back plugs 4 (the connections are shown in FIG. 1).

In step S3, the configuration module 120 defines the testing parameters and reference parameters according to testing requirements, and defines the reference values corresponding to the testing parameters. The testing parameters and the reference parameters are shown in corresponding dialogue boxes on the user interface 100, and the reference values are modifiable in corresponding dialogue boxes on the user interface 100 through the configuration module 120.

In step S5, the transmitting module 130 imports the test file that includes the test data, and transmits the test data into the transmission loop according to the reference values of the testing parameters. While transmitting the test data, the predefined dialogue boxes on the user interfaces 100 displays different relating information in real time. For example, the data-transmitting dialogue box 102 displays the transmitted data, the baud rate curve 105 shows changes of the baud rate while transmitting the test data, and the signal status dialogue box 106 displays different colors indicating different signal statuses of the pins of the serial port 3 (as shown in FIG. 3).

In step S7, the receiving module 140 receives data from the transmission loop, and acquires the actual values of the testing parameters.

In step S9, the analyzing module 150 analyzes whether the signal statuses of the pins of the serial port 3 are correct according to the colors displayed in the signal status dialogue box 106. If the signal statuses of the pins of the serial port 3 are correct, in step S11, the analyzing module 150 compares the actual values with the reference values of the testing parameters, and analyzes whether the actual values and the reference values are identical. Otherwise, if the signal statuses of the pins of the serial port 3 are incorrect, the procedure goes directly to step S17.

If the actual values and the reference values are identical, in step S13, the analyzing module 150 compares the received data with the transmitted data according to the verification means, and analyzes whether the received data and the transmitted data are identical. Otherwise, if the actual values and the reference values are not identical, the procedure directly goes to step S17.

If the received data and the transmitted data are identical, the analyzing module 150 analyzes the serial port 3 to be in a good working condition. Otherwise, if the received data and the transmitted data are not identical, in step S17, the analyzing module 150 analyzes that the serial port has errors, and prompts the errors on the user interface.

The testing procedure can be defined to repeat one more times for obtaining more accurate test results.

It should be emphasized that the above-described embodiments, particularly, any “preferred” embodiments, are merely possible examples of implementations, merely set forth for a clear understanding of the principles of the invention. Many variations and modifications may be made to the above-described preferred embodiment(s) without departing substantially from the spirit and principles of the invention. All such modifications and variations are intended to be included herein within the scope of this disclosure and the above-described preferred embodiment(s) and protected by the following claims.

What is claimed is:

1. A system for testing a serial port, the system comprising:
a creating module configured for creating a transmission loop by connecting pins of the serial port;
a configuration module configured for defining testing parameters and reference values corresponding to the testing parameters;
a transmitting module configured for importing a test file that comprises test data, for transmitting the test data into the transmission loop according to the reference values of the testing parameters;
a receiving module configured for acquiring actual values of the testing parameters during transmitting, for receiving data from the transmission loop; and
an analyzing module configured for comparing the transmitted data with the received data, for comparing the actual values with the reference values of the testing parameters, and for analyzing whether the serial port is in a good working condition according to comparison results.

2. The system according to claim 1, wherein the connections between the pins of the serial port comprise:
a connection between a RxD pin and a TxD pin of the serial port;
a connection between a RTS pin and a CTS pin of the serial port; and
a connection between a DCD pin, a DTR pin and a DSR pin of the serial port.

3. The system as claimed in claim 1, wherein the analyzing module is further configured for comparing the transmitted data and the received data according to a plurality of verification means which comprises a parity check, a cyclic redundancy check, and a checksum verification.

4. The system as claimed in claim 1, wherein the analyzing module is further configured for analyzing that the serial port has errors and prompting the errors if the transmitted data and the received data are not identical.

5. The system as claimed in claim 1, wherein the analyzing module is further configured for analyzing that the serial port has errors and prompting the errors if the actual values and the reference values of the testing parameters are not identical.

6. A method for testing a serial port, the method comprising the steps of:
creating a transmission loop by connecting pins of the serial port;
defining testing parameters, and reference values corresponding to the testing parameters;
importing a test file that comprises test data;
transmitting the test data into the transmission loop according to the reference values of the testing parameters;
acquiring actual values of the testing parameters during transmitting;
receiving data from the transmission loop;
comparing the transmitted data with the received data and comparing the actual values with the reference values of the testing parameters; and
analyzing whether the serial port is in a good working condition according to comparison results.

7. The method according to claim 6, wherein the connections between the pins of the serial port comprise:
a connection between a RxD pin and a TxD pin of the serial port;
a connection between a RTS pin and a CTS pin of the serial port; and
a connection between a DCD pin, a DTR pin and a DSR pin of the serial port.

8. The method according to claim 6, further comprising the step of:
analyzing that the serial port has errors and prompting the errors if the transmitted data and the received data are not identical.

9. The method according to claim 6, further comprising the step of:
analyzing that the serial port has errors and prompting the errors if the actual values and the reference values of the testing parameters are not identical.

10. The method according to claim 6, further comprising the steps of:
defining different colors corresponding to different signal statuses of the pins respectively, the signal statuses comprising a high level status, a low level status, and a twinkling status;
defining a user interface and a signal status dialogue box therein configured for displaying the predefined colors corresponding to the signal statuses of the pins; and
analyzing whether the signal statuses of the pins are correct according to the colors displayed in the signal status dialogue box.

11. The method according to claim 6, further comprising the step of comparing the transmitted data with the received data according to a plurality of verification means which comprises a parity check, a cyclic redundancy check, and a checksum verification.

12. A system for testing a serial port, the system comprising:
a creating module configured for creating a transmission loop by connecting pins of the serial port;
a configuration module configured for defining testing parameters and reference values corresponding to the testing parameters, and for defining a user interface comprising a plurality of dialogue boxes for displaying the testing parameters and the corresponding reference values;
a transmitting module configured for importing a test file that comprises test data, for transmitting the test data into the transmission loop according to the reference values of the testing parameters;
a receiving module configured for acquiring actual values of the testing parameters during transmitting, for receiving data from the transmission loop; and
an analyzing module configured for comparing the actual values with the reference values of the testing parameters, and for analyzing whether the serial port is in a good working condition according to a comparison result.

13. The system according to claim 12, wherein the connections between the pins of the serial port comprise:
a connection between a RxD pin and a TxD pin of the serial port;
a connection between a RTS pin and a CTS pin of the serial port; and
a connection between a DCD pin, a DTR pin and a DSR pin of the serial port.

14. The system as claimed in claim 12, wherein the configuration module is further configured for defining different colors corresponding to different signal statuses of the pins of the serial port, the signal statuses comprising a high level status, a low level status, and a twinkling status.

15. The system as claimed in claim 14, wherein the configuration module is further configured for defining a signal status dialogue box to display the colors corresponding to different signal statuses of the pins.

16. The system as claimed in claim 15, wherein the analyzing module is further configured for analyzing whether the signal statuses of the pins are correct according to a comparison of the colors displayed in the signal status dialogue box with the predefined colors.
